(19) United States
(12) Patent Application Publication
(10) Pub. No.: US 2024/0355897 A1
(43) Pub. Date: Oct. 24, 2024

(54) SEMICONDUCTOR DEVICES WITH LOW BARRIER HEIGHT SCHOTTKY CONTACTS

(71) Applicant: Wolfspeed, Inc., Durham, NC (US)

(72) Inventors: Neal Oldham, Apex, NC (US); In-Hwan Ji, Apex, NC (US); Edward Van Brunt, Cary, NC (US); Rahul R. Potera, Apex, NC (US); Jae-Hyung Park, Apex, NC (US)

(21) Appl. No.: 18/138,240

(22) Filed: Apr. 24, 2023

(51) Int. Cl. H01L 29/47; H01L 21/04; H01L 29/16; H01L 29/66; H01L 29/872

(52) U.S. Cl. CPC H01L 29/47; H01L 21/0465; H01L 21/0495; H01L 29/1608; H01L 29/6606; H01L 29/872

(57) ABSTRACT

A Schottky diode according to some embodiments includes a silicon carbide drift layer having a first conductivity type, and a junction shielding region in the drift layer. The junction shielding region has a second conductivity type opposite the first conductivity type. The Schottky diode further includes an anode contact on the silicon carbide drift layer. The anode contact includes a refractory metal nitride, and forms a Schottky junction with the drift layer and an ohmic contact to the junction shielding region.

### BACKGROUND

The present disclosure relates to semiconductor device structures and in particular to power semiconductor devices including silicon carbide Schottky diodes and metal-oxide semiconductor field effect transistors (MOSFETs).

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group III nitrides (e.g., 3.36 eV for GaN at room temperature). These materials may have higher electric field breakdown strengths and higher electron saturation velocities than GaAs and Si.

One important application for wide bandgap semiconductors such as silicon carbide is in Schottky diodes.

A Schottky diode, also known as Schottky barrier diode, is a semiconductor diode formed by the junction of a semiconductor with a metal. The metal-semiconductor junction (instead of a semiconductor-semiconductor junction as in conventional PN-junction diodes) in a Schottky diode creates a Schottky barrier. The metal side acts as the anode, and an n-type semiconductor acts as the cathode of the diode. When sufficient forward voltage is applied to overcome the Schottky barrier of the metal-semiconductor junction, current flows through the device in the forward direction. When a reverse voltage is applied, a depletion region is formed in the semiconductor, obstructing current flow.

Compared to a conventional PN-junction diode, a Schottky diode has a low forward voltage drop and a very fast switching action.

An important difference between a PN-junction diode and a Schottky diode is the reverse recovery time (tᵣᵣ), which it the time it takes of the diode to switch from a conducting (forward biased) state to a non-conducting (reverse biased) state. In the conducting state, a conventional PN-junction diode injects minority carriers into the diffusion region on the N-side of the junction where they recombine with majority carriers after diffusion. The reverse recovery time of a PN-junction is primarily limited by the diffusion capacitance of minority carriers accumulated in the diffusion region during the conducting state.

In contrast, a Schottky diode is a unipolar or “majority carrier” device that does not rely on minority carrier injection. Rather, in the conducting state, majority carriers (electrons in the case of an n-type semiconductor layer) are injected across the junction. Thus, switching a Schottky diode from a conducting to a non-conducting state does not require time for recombination of the injected carriers. Rather, the switching speed of a Schottky diode is only limited by the junction capacitance of the device.

Silicon carbide Schottky diodes are the rectifiers of choice in advanced power electronics at 650V and above, primarily because they achieve fast switching speeds with much lower leakage current and capacitance than silicon-based Schottky diodes.

For example, in power supply boost convertors, a SiC Schottky diode may be required to carry a surge current that is about ten to fifteen times the rated current of the device for a short interval of several milliseconds. A so-called Merged PN-Schottky (MPS) diode facilitates this by merging islands of PN junctions into the Schottky diode, so that at high forward currents, the PN junctions between the islands and the drift layer can turn on, enabling conductivity modulation of the drift layer and carrying surge current at lower voltages than traditional Schottky diodes.

### SUMMARY

A Schottky diode according to some embodiments includes a silicon carbide drift layer having a first conductivity type, and a junction shielding region in the drift layer. The junction shielding region has a second conductivity type opposite the first conductivity type. The Schottky diode further includes an anode contact on the silicon carbide drift layer. The anode contact includes a refractory metal nitride, and forms a Schottky junction with the drift layer and an ohmic contact to the junction shielding region.

The anode contact many have a Schottky barrier height relative to the drift layer of less than about 1.2 eV, and in some embodiments less than about 1 eV. The anode contact may include (Mo) nitride. The anode contact may have a molecular ratio x of nitrogen of greater than about 0.5, and in some embodiments between about 1.0 and 1.6.

The anode contact may have a thickness of at least about 50 nm, and in some embodiments the anode contact has a thickness of between about 50 nm and 300 nm. The anode contact may have a level of residual stress as deposited on the drift layer that has a magnitude of less than about 500 MPa.

The anode contact may include a plurality of refractory metal nitride portions and a plurality of non-refractory metal nitride portions that are arranged in an alternating pattern along a surface of the drift layer. The non-refractory metal nitride portions may form a Schottky barrier junction with the drift layer that has a greater Schottky barrier height than the refractory metal nitride portions form with the drift layer.

The Schottky diode may further include a plurality of junction shielding regions in the drift layer, wherein the refractory metal nitride portions are arranged above the junction shielding regions and form respective ohmic contacts with the junction shielding regions.

The non-refractory metal nitride portions may contact the drift layer between adjacent junction shielding regions. The non-refractory metal nitride portions may include Ti and/or TiW.

The anode contact may include alternating first and second regions along a surface of the drift layer, wherein the first regions have a first Schottky barrier height relative to the drift layer that is higher than a second Schottky barrier height of the second regions relative to the drift layer.

The first regions may include MoNₓ and the second regions may include MoN_{y}, wherein x>y.

A nitrogen concentration in the anode contact may be graded laterally between the first regions and the second regions. In some embodiments, the nitrogen concentration in the anode contact is smoothly graded between the first regions and the second regions, and in some embodiments, the nitrogen concentration in the anode contact is stepwise graded between the first regions and the second regions.

The Schottky diode may further include a plurality of trenches in an upper surface of the drift layer, wherein the anode contact may include a plurality of refractory metal nitride portions in the trenches and a metal layer on the upper surface of the drift layer, wherein the metal layer contacts the refractory metal nitride portions.

The metal layer may form a first Schottky junction with the drift layer and the refractory metal nitride portions form second Schottky junctions with the drift layer, wherein the first Schottky junction has a higher Schottky barrier height than the second Schottky junctions.

The Schottky diode may further include a plurality of junction shielding regions in the drift layer, wherein the junction shielding regions are arranged beneath respective ones of the trenches, and wherein the refractory metal nitride regions form ohmic contacts to respective ones of the junction shielding regions.

The refractory metal nitride regions may include MoNₓ, and the metal layer may include molybdenum, titanium and/or tungsten.

The Schottky diode may further include a plurality of silicide regions on the drift layer between the drift layer and the anode contact. The silicide regions may include MoSi.

The Schottky diode may further include a plurality of junction shielding regions in the drift layer, wherein the plurality of silicide regions are arranged above respective ones of the plurality of junction shielding regions and form ohmic contacts to the junction shielding regions.

The silicide regions may be provided within respective trenches in the drift layer, and wherein the junction shielding regions are beneath the trenches. The anode contact may extend into the trenches.

A method of forming a Schottky diode includes forming a drift layer on a substrate, wherein the drift layer and the substrate may include silicon carbide and have a first conductivity type, forming a junction shielding region at a surface of the drift layer, wherein the junction shielding region has a second conductivity type opposite the first conductivity type, and forming an anode contact on the drift layer, wherein the anode contact includes a refractory metal nitride, and wherein the anode contact forms a Schottky junction with the drift layer.

### BRIEF DESCRIPTION OF THE DRAWINGS

FIG. 1 illustrates a conventional Schottky diode.

FIG. 2 illustrates a Schottky diode according to some embodiments.

FIG. 3 is a graph of forward current as a function of anode voltage (V_{A}) for Schottky contacts formed of titanium (curve 302), molybdenum (curves 304a, 304b) and MoNₓ (curve 306).

FIG. 4 is a graph of deposition rate (via sputtering) of a layer of MoNx as a function of the fraction of N₂ in the sputtering chamber relative to a mixture of an N₂/Ar gases in the chamber.

FIG. 5 is a graph that illustrates the effect of the fraction of N₂ in the sputtering chamber relative to a mixture of an N₂/Ar gases in the chamber on residual stress in the MoNₓ layer.

FIGS. 6A to 6D illustrate operations for forming the active region of a Schottky diode structure according to some embodiments.

FIG. 7 illustrates the active region of a SiC Schottky diode according to further embodiments.

FIG. 8 illustrates a SiC Schottky diode according to some embodiments in which the anode contact includes a non-MoNₓ layer formed on the surface of the epitaxial layer.

FIG. 9 illustrates an active region of a Schottky diode structure according to some embodiments in which an anode contact is provided.

FIG. 10 illustrates an active region of a Schottky diode according to some embodiments.

FIG. 11 illustrates a SiC Schottky diode according to some embodiments in which the anode contact includes an MoNₓ layer formed on the surface of the epitaxial layer.

FIG. 12 illustrates operations for forming a Schottky diode according to some embodiments.

FIGS. 13A and 13B illustrate operations of forming a semiconductor device according to some embodiments.

FIGS. 14A to 14C illustrate operations of forming a semiconductor device according to some embodiments.

### DETAILED DESCRIPTION OF EMBODIMENTS

Embodiments of the inventive concepts will now be described in connection with the accompanying drawings.

Silicon carbide Schottky diodes are well suited for use in advanced power electronics at voltages of 650V and above, primarily because they achieve fast switching speeds with much lower leakage current and capacitance than silicon Schottky diodes. In power supply boost convertors, a SiC Schottky diode is required to carry a surge current of about 10-15× the rated current for a short interval of several milliseconds. So-called MPS (Merged PN-Schottky) diodes accomplish this by merging islands of P-N junctions into the Schottky diode so that at high forward currents, the P-N junction can turn on, which enables conductivity modulation of the drift layer and allows the device to conduct surge current at lower voltages than conventional Schottky diodes.

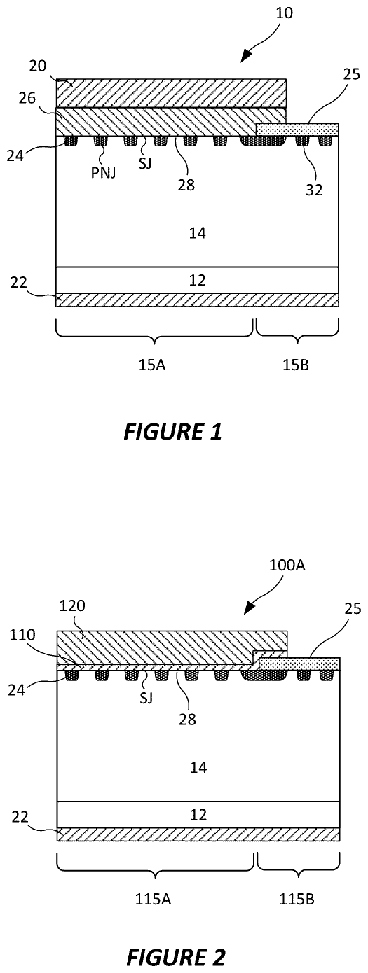

A portion of an MPS Schottky diode 10 is illustrated in cross-section in FIG. 1. The Schottky diode 10 includes an active area 15A and an edge termination area 15B (also called a junction termination region, or simply a termination region) that is outside the active area.

An n-silicon carbide epitaxial layer 14 is formed on a silicon carbide substrate 12. The silicon carbide epitaxial layer 14 and the silicon carbide substrate may comprise a 2H, 4H, 6H, 3C or 15R polytype of silicon carbide, where “polytype” refers to the way in which the atoms of the material are arranged in a crystal lattice. In this context, “n-” refers to the conductivity type of the silicon carbide material, and indicates that it is lightly doped with n-type dopants. A semiconductor substrate, layer or region can be doped with impurities that cause the material to have an excess of either positively charged (p-type) or negatively charged (n-type) charge carriers, which defines the conductivity type of the material. A “+” or “−” sign is used to indicate that a particular region or layer of the semiconductor material is more or less heavily doped than another region or layer. For example, materials described as “n−” are more lightly doped, with lower concentrations of n-type dopants than an n-type layer, while materials described as “n+” are more heavily doped, with higher concentrations of n-type dopants than an n-type layer.

A metal anode contact 26 is formed on the surface of the silicon carbide epitaxial layer 14 opposite the substrate 12. The anode contact 26 is typically formed from titanium or titanium tungsten, and forms a Schottky barrier junction SJ with the silicon carbide epitaxial layer 14.

A metal overlayer 20 is formed on the anode contact. The metal overlayer 20 may comprise gold and may facilitate wirebonding or other contact formation to the diode 10.

At the surface of the silicon carbide epitaxial layer 14, a plurality of p+ junction shielding regions 24 are formed at the surface of the silicon carbide epitaxial layer 14. The p+ junction shielding regions 24 may be formed by ion implantation to form P-N junctions PNJ with the silicon carbide epitaxial layer 14. The anode contact 26 forms ohmic contact to the p+ junction shielding regions 24.

A cathode ohmic contact 22 is formed on the back side of the substrate 12.

Although described in terms of a device including an n-type epitaxial layer 14 and p-type junction shielding regions 24, it will be appreciated that in some embodiments the conductivity types may be reversed, i.e., a p-type epitaxial layer with n-type shielding regions.

The Schottky barrier junction SJ between the anode contact 26 and the silicon carbide epitaxial layer 14, which is formed on exposed regions 28 of the silicon carbide epitaxial layer 14 between the p+ junction shielding regions 24, has a lower Schottky barrier height (or barrier energy) than the P-N junctions PNJ between the p+ junction shielding regions 24 and the silicon carbide epitaxial layer 14. For example, when the anode contact 26 comprises titanium, the anode contact 26 has a Schottky barrier height of about 1.20 to 1.26 eV. This allows the Schottky barrier junction SJ to turn on before the P-N junctions PNJ in the forward biased (conducting) state. Conversely, in the reverse biased (non-conducting) state, the Schottky barrier junction SJ is shielded from high electric fields by the depletion region formed at the interface of the P-N junctions PNJ and the silicon carbide epitaxial layer 14.

In the edge termination area 15B, a plurality of floating guard rings 32 (also called equipotential rings or field rings) are formed in respective regions 31 at the surface of the silicon carbide epitaxial layer 14. The guard rings 32 may comprise implanted p+ regions in the silicon carbide epitaxial layer 14. A silicon nitride passivation layer 25 is formed over the edge termination area 15B. A protective layer (not shown) of a material such as polyimide may be formed on the silicon nitride passivation layer 25.

At lower current densities, forward current is carried across the Schottky barrier junction. The Schottky barrier height (PHIbn or SBH) limits the conductivity of the n-type regions of the device at lower current densities. Although the Schottky barrier height of metal contacts on silicon carbide that are formed of metals such as titanium and titanium tungsten is quite low, devices formed with such contacts may nevertheless have a undesirably high voltage drop across the Schottky barrier junction at low current densities.

Reducing the barrier height by using a different material as the Schottky contact metal may reduce the voltage drop across the n-type regions, and thus may improve the overall efficiency of the device.

Accordingly, some embodiments described herein provide silicon carbide-based Schottky diodes having low Schottky barrier height, or more succinctly low barrier height, Schottky contacts. In this context, a low Schottky barrier height refers to a Schottky barrier height of a Schottky contact to silicon carbide that is below about 1.2 eV. In particular, a refractory metal nitride material, such as molybdenum nitride may be used to form anode contact having a low Schottky barrier height. Other refractory metal nitride materials that may be used include, for example, tungsten nitride and tantalum nitride. Molybdenum nitrides (MoNₓ) in particular exhibit a Schottky barrier height on 4H-SiC of about 0.8 eV to 1.2 eV. Because of this lower SBH when MoNₓ is used as the Schottky barrier metal, the voltage drop across the junction decreases at lower current densities. Power consumption of the device may be reduced proportionally, which may improve the efficiency of the device.

FIG. 2 illustrates a SiC based MPS Schottky diode 100A. The diode 100A includes an n-type silicon carbide substrate 12 on which an n-type silicon carbide epitaxial layer 14 is formed. The epitaxial layer 14 functions as the drift layer of the diode 100A. The diode 100A includes a plurality of junction shielding region 24 at the surface of the epitaxial layer.

An anode contact 110 is formed on the epitaxial layer 14 in the active region 115A of the diode 100A. The anode contact 110 comprises a layer of a refractory metal nitride such as MoNₓ, which forms a low barrier height Schottky junction SJ to exposed portions of the epitaxial layer 14 between the junction shielding regions 24. The layer of refractory metal nitride may have a thickness of at least about 0.05 microns, and may be in a range of about 0.05 to 0.30 microns. The molecular ratio of nitrogen in the refractory metal nitride layer (indicated by the subscript x) may be greater than about 0.5, and may range from about 1.0 to about 1.6 in some embodiments.

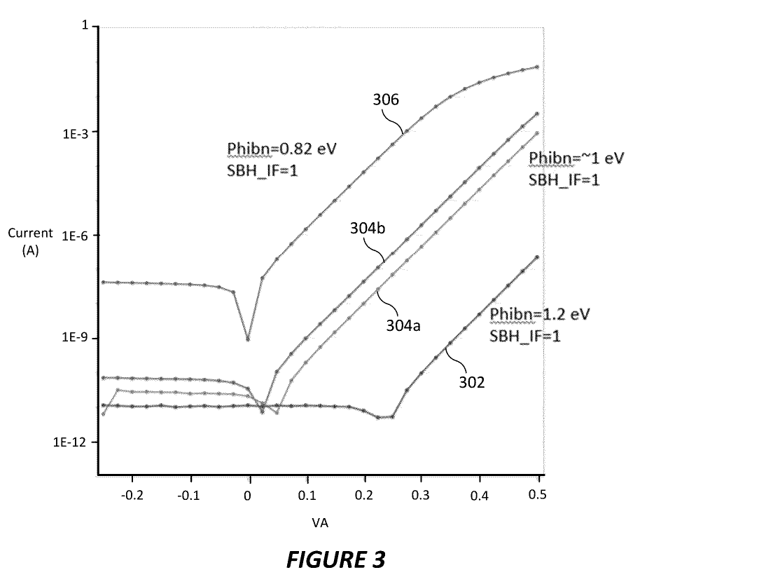

The nitrogen content of the refractory metal nitride layer may affect the Schottky barrier height of the anode contact 110. In particular, the Schottky barrier height of an anode contact 110 formed of MoNₓ may decrease as the fraction x of nitrogen in the MoNₓ layer increases. For example, FIG. 3 is a graph of forward current as a function of anode voltage (V_{A}) for Schottky contacts formed of titanium (curve 302), molybdenum (curves 304a, 304b) and MoNₓ (curve 306). The MoNx Schottky contact had a Schottky barrier height of 0.82 eV, while the Mo Schottky contacts had a Schottky barrier height of about 1 eV, and the Ti Schottky contact had a Schottky barrier height of 1.2 eV. Accordingly, as seen in FIG. 3, the MoNₓ Schottky contacts showed significantly higher current than the Mo or Ti Schottky contacts at low current densities for V_{A} less than about 0.5 V.

Accordingly, it may be desirable to increase the fraction x of nitrogen in the refractory metal nitride as much as possible. However, there are design trade-offs with doing so, as the fraction x of nitrogen in the refractory metal nitride also affects material properties of the layer, such as residual stress in the layer. The fraction x of nitrogen in the refractory metal nitride may also impact manufacturing parameters, such as the deposition rate of the material.

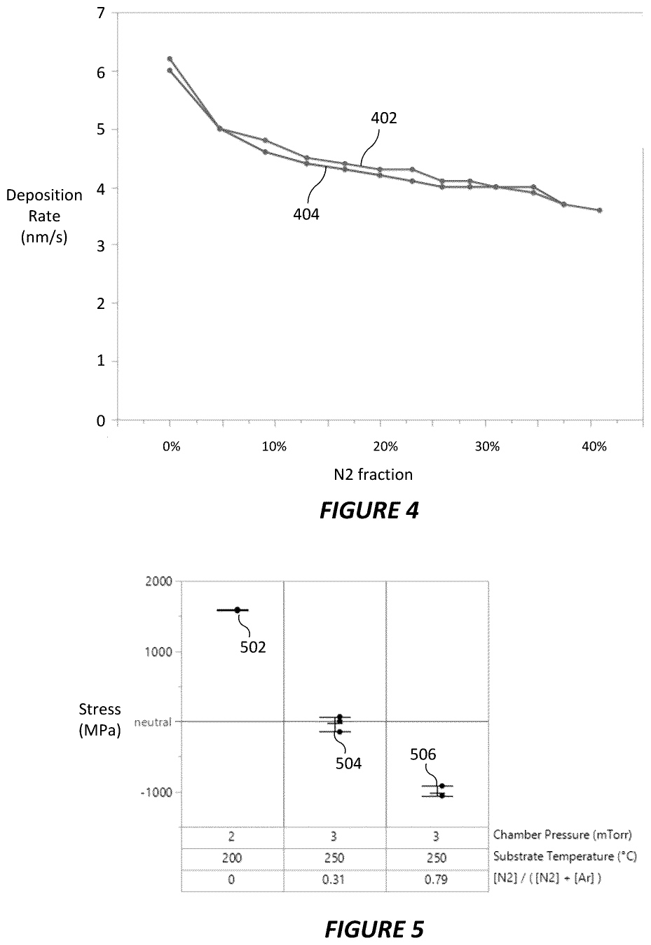

For example, FIG. 4 is a graph of deposition rate (via sputtering) of a layer of MoNx as a function of the fraction of N₂ in the sputtering chamber relative to a mixture of an N₂/Ar gases in the chamber. As illustrated in FIG. 4, as the ratio increases (indicating more N in the chamber and hence a higher fraction x of nitrogen in the deposited MoNₓ layer), the deposition rate of the material decreases.

FIG. 5 is a graph that illustrates the effect of the fraction of N₂ in the sputtering chamber relative to a mixture of an N₂/Ar gases in the chamber on residual stress in the MoNₓ layer. As shown in FIG. 5, when no N₂ is used (corresponding to a Mo layer, or a MoNₓ layer with x=0), the resulting film has a positive (tensile) stress of about 1500 MPa. When the fraction of N₂ in the sputtering chamber relative to a mixture of an N₂/Ar gases in the chamber is about 0.31, the residual stress in the film is negligible. When the fraction of N₂ in the sputtering chamber relative to a mixture of an N₂/Ar gases in the chamber is about 0.79, the residual stress in the film is about −1000 MPa, and is compressive. In general, it is desirable to have lower stress in the deposited film to reduce the chance of cracking or other defect formation.

Other process factors may affect the barrier height of an MoNx-SiC interface. For example, it has been reported that the Schottky barrier height of a MoNx-SiC interface is inversely related to the deposition temperature. However, it has also been reported that the Schottky barrier height of a MoNx-SiC interface is directly related to the deposition temperature. Accordingly, it is believed that the barrier height of an MoNx-SiC interface may be dependent on multiple process conditions.

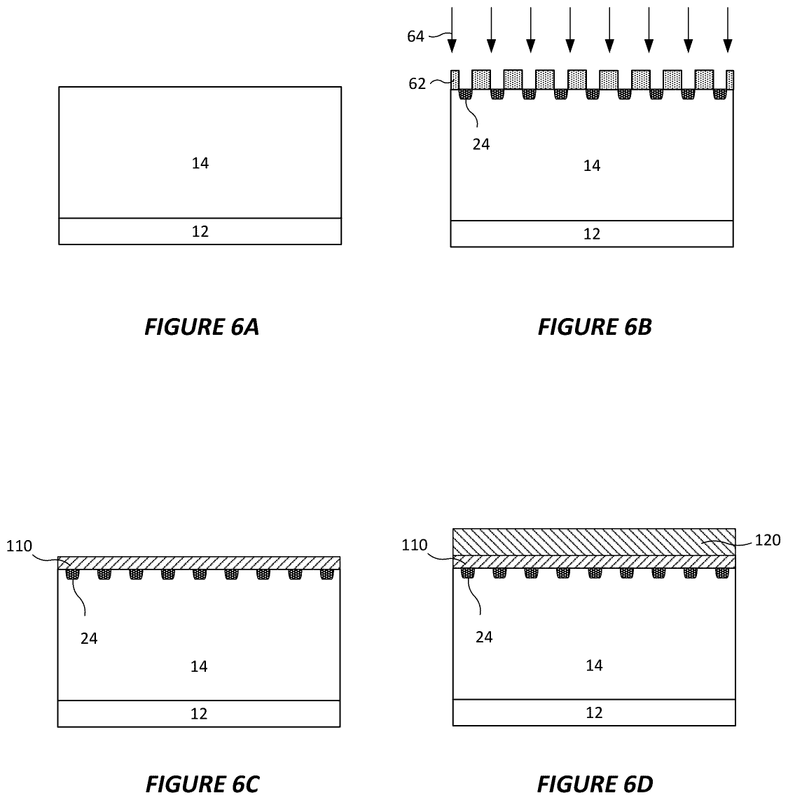

Operations for forming the active region of a Schottky diode structure 100A according to some embodiments are illustrated in FIGS. 6A to 6D. Referring to FIG. 6A, a silicon carbide substrate 12 is provided. The silicon carbide substrate 12 may have a 2H, 4H, 6H, 3C and/or 15R polytype, and may have an off-axis orientation of about 1 to 3 degrees from a <0001> crystallographic direction. The silicon carbide substrate 12 may be doped with n-type dopants, such as nitrogen and/or phosphorus. A silicon carbide epitaxial layer 14 is grown via epitaxial growth on the silicon carbide substrate 12. The silicon carbide epitaxial layer 14 may be lightly doped with n-type dopants to have an n-conductivity.

Referring to FIG. 6B, an implant mask 62 is formed on the silicon carbide epitaxial layer, and p-type dopant ions 64 are implanted into the silicon carbide epitaxial layer 14 to form junction shielding regions 24.

Referring to FIG. 6C, a film of refractory metal nitride, such as MoNₓ, is deposited on the silicon carbide epitaxial layer 14 to form an anode contact 110. The refractory metal nitride may be deposited, for example, by sputtering a refractory metal such as Mo onto the silicon carbide epitaxial layer 14 in an ambient environment containing nitrogen (N₂) and argon (Ar). In particular, the level of nitrogen contained in the ambient may be selected so that the refractory metal nitride film has a desired fraction of nitrogen so that the anode contact 110 has a Schottky barrier height relative to the silicon carbide epitaxial layer 14 of less than about 1 eV. The level of nitrogen contained in the ambient may also be selected with consideration of the effect of the resulting level of nitrogen in the refractory metal nitride film on the amount and type (e.g., compressive or tensile) of stress in the film.

Referring to FIG. 6D, a metal overlay 120 is formed on the anode contact 110. The metal overlay 120 may comprise a material such as gold that enables formation of a wirebond thereon. Other metals and/or metal layers may be provided in the metal overlay 120, such as one or more barrier or adhesion layers.

In a Schottky barrier diode with a refractory metal nitride anode contact, although the lowered Schottky barrier height of the metal-semiconductor junction may provide a reduced forward voltage drop with improved efficiency during forward conduction, such devices may be more prone to leakage current in reverse blocking conditions. To alleviate this issue, some embodiments provide an anode contact having alternating regions of higher and lower Schottky barrier height, where the regions of lower Schottky barrier height are arranged near or above the junction shielding regions 24 so that the junction shielding regions 24 can protect the regions of lower Schottky barrier height during reverse blocking conditions.

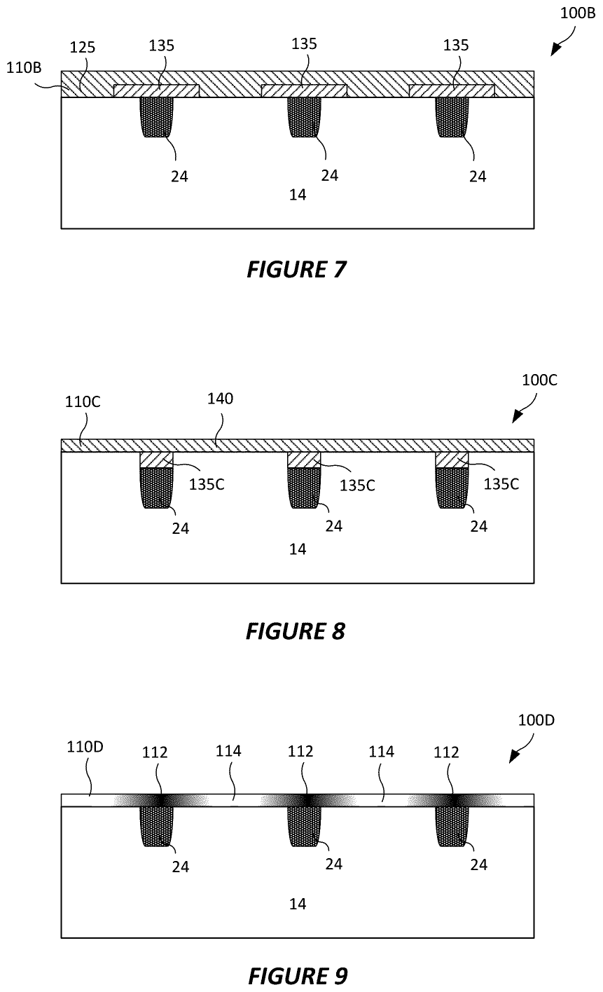

For example, FIG. 7 illustrates the active region of a SiC Schottky diode 100B according to further embodiments. In the embodiments illustrated in FIG. 7, the anode contact 110B comprises an alternating arrangement of refractory metal nitride portions 135 and a non-refractory metal nitride portion 125 that contacts the epitaxial layer 14 between the refractory metal nitride portions 135. The non-refractory metal nitride layer 125 may include a metal such as Ti or TiW that forms a Schottky barrier junction to the epitaxial layer 14 with a higher Schottky barrier junction than the refractory metal nitride portions 135B have.

The refractory metal nitride portions 135B are arranged above the junction shielding regions 24, while the non-refractory metal nitride layer 125 is arranged in areas between the junction shielding regions 24. In this arrangement, the refractory metal nitride portions 135B provide increased current at low forward voltages, thereby increasing efficiency of operation while being protected against high reverse blocking voltages by the junction shielding region 24. In portions of the anode contact 110 that are between the junction shielding regions 24 (and not as protected by the junction shielding regions 24), the non-refractory metal nitride layer 125 of the anode contact 110B is provided.

FIG. 8 illustrates a SiC Schottky diode 100C in which the anode contact 110C includes a non-refractory metal nitride layer 140 formed on the surface of the epitaxial layer 14. Refractory metal nitride regions 135C are provided in trenches thin the epitaxial layer 14 above the junction shielding regions 24 and in contact with the non-refractory metal nitride layer 140. As with the embodiment illustrated in FIG. 7, the refractory metal nitride portions 135C provide increased current at low forward voltages, thereby increasing efficiency of operation while being protected against high reverse blocking voltages by the junction shielding region 24. The refractory metal nitride portions 135C may have a thickness in the vertical dimension of about 0.3 microns to 0.5 microns.

The non-refractory metal nitride layer 140 of the anode contact 110C is provided In portions of the anode contact 110 that are between the junction shielding regions 24 (and thus is not as protected by the junction shielding regions 24 as the refractory metal nitride portions 135C). The non-MoNₓ layer 140 may include a material such as Ti or TiW, and may form a Schottky junction with the epitaxial layer 14 that has a higher Schottky barrier height than the refractory metal nitride in the refractory metal nitride regions 135C.

FIG. 9 illustrates an active region of a Schottky diode structure 100D in which an anode contact 110D is provided. The anode contact 110D is formed of a refractory metal nitride such as MoNₓ with varying percentages of nitrogen across the active region. In particular, the anode contact 110D includes first regions 112 of refractory metal nitride having a high percentage of nitrogen and second regions 114 of refractory metal nitride having a lower percentage of nitrogen. The first regions 112 are arranged above the junction shielding regions 24, while the second regions 114 are positioned above the epitaxial layer 14 in regions between the junction shielding regions 24. Because the first regions 112 have a higher nitrogen concentration, they may have a lower Schottky barrier height than the second regions 114, which have a lower nitrogen concentration.

The grading of nitrogen concentrations between the first regions 112 and the second regions 114 may be smooth as indicated by graded shading in FIG. 9, or may be stepwise graded in a single step or multiple steps.

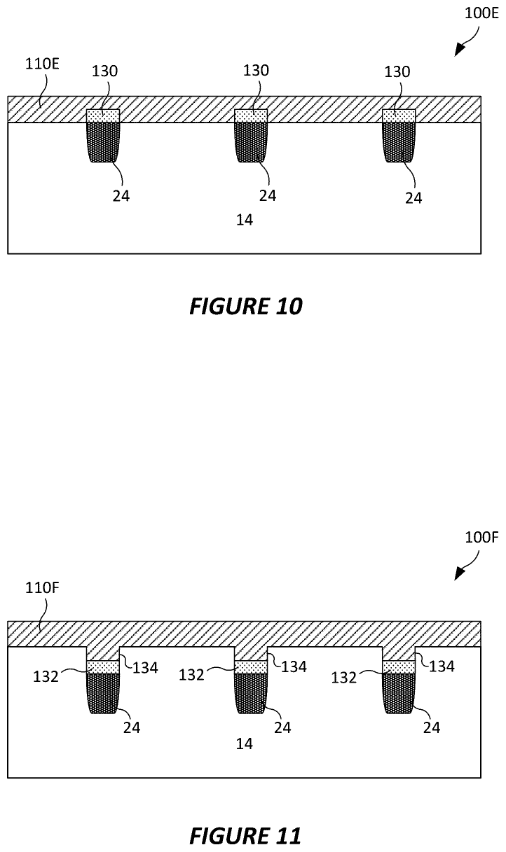

FIG. 10 illustrates an active region of a Schottky diode 100E according to some embodiments. The Schottky diode 100E includes an anode contact 110E formed of a refractory metal nitride. Within the anode contact 110E, regions 130 of a refractory metal silicide, such as MoSiₓ are formed above the junction shielding regions 24 as planar silicide ohmic contacts to the junction shielding regions 24. The planar arrangement shown in FIG. 10 may have less effective shielding than a trench arrangement as shown in FIG. 8. However, the planar arrangement may have a simpler manufacturing process, since no trenches need to be formed.

The embodiment illustrated in FIG. 10 leverages the ohmic nature of the silicide contact to the p+ silicon carbide of the junction shielding regions 24, along with the rectifying nature of the refractory metal nitride contact to n-type silicon carbide of the epitaxial layer 14. The contact between the refractory metal nitride portion of the anode contact 110E and the silicide portions 130 is metallic, i.e., ohmic and non-rectifying.

FIG. 11 illustrates a SiC Schottky diode 100F in which the anode contact 110F includes a refractory metal nitride layer formed on the surface of the epitaxial layer 14. Refractory metal silicide (e.g., MoSiₓ) regions 132 are provided in trenches 134 in the epitaxial layer 14 above the junction shielding regions 24. The silicide regions 132 are in contact with the anode contact 110F. The silicide portions 132 form ohmic contact to the junction shielding regions 24. The refractory metal nitride of the anode contact 110C forms a Schottky barrier junction with the epitaxial layer 14 between the trenches 134. The refractory metal nitride of the anode contact 110dC may extend into the trenches 134 as shown in FIG. 11.

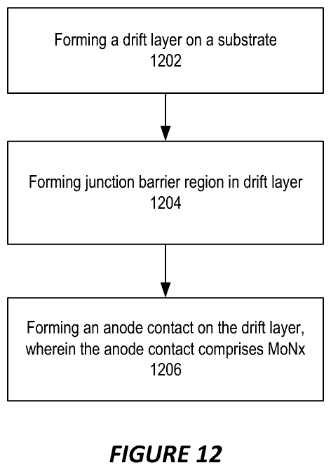

FIG. 12 illustrates operations of forming a Schottky diode according to some embodiments. Referring to FIG. 12, the operations include forming a drift layer on a substrate, wherein the drift layer and the substrate comprise silicon carbide and have a first conductivity type (block 1202), forming a junction shielding region at a surface of the drift layer, wherein the junction shielding region has a second conductivity type opposite the first conductivity type (block 1204), and forming an anode contact on the drift layer, wherein the anode contact comprises a refractory metal nitride such as MoNx, and wherein the anode contact forms a Schottky junction with the drift layer.

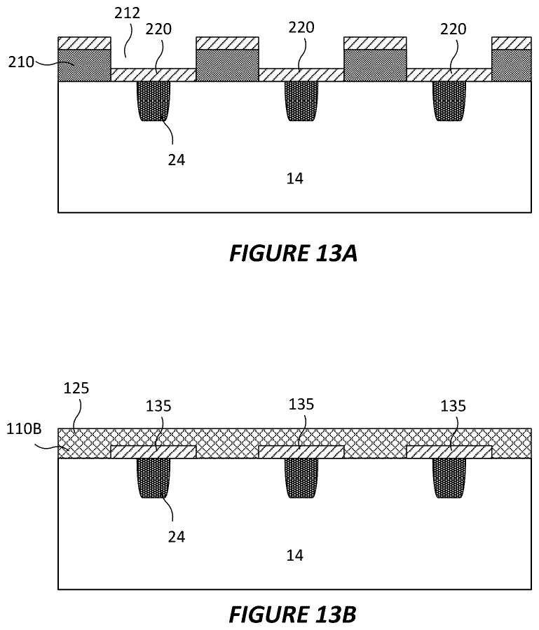

FIGS. 13A and 13B illustrate operations of forming a semiconductor device according to some embodiments. In particular, FIGS. 13A and 13B illustrate operations of forming a device structure 100B as shown in FIG. 7 in which the anode contact 110B comprises a non-refractory metal nitride layer 125 and a plurality of refractory metal nitride portions 135. The non-refractory metal nitride portions 125 may include a metal such as Ti or TiW that forms a Schottky barrier junction to the epitaxial layer 14 with a higher Schottky barrier junction than the refractory metal nitride portions 135B have.

Referring to FIG. 13A, a mask 210 is formed on the epitaxal layer 14, and is patterned with openings 212 that expose portions of the epitaxial layer 14 in which the junction shielding regions 24 are formed. A blanket layer of a refractory metal nitride, such as MoNₓ, is deposited over the mask 210 and the exposed portions of the epitaxial layer 14. The mask 210 is the stripped, leaving the plurality of refractory metal nitride portions 135 on the epitaxial layer 14. A layer 125 of a non-refractory metal nitride, such as tungsten and/or titanium, is then deposited over the structure. The layer 125 contacts the expitaxial layer 14 between the refractory metal nitride portions 135 and forms a Schottky contact to the epitaxial layer 14.

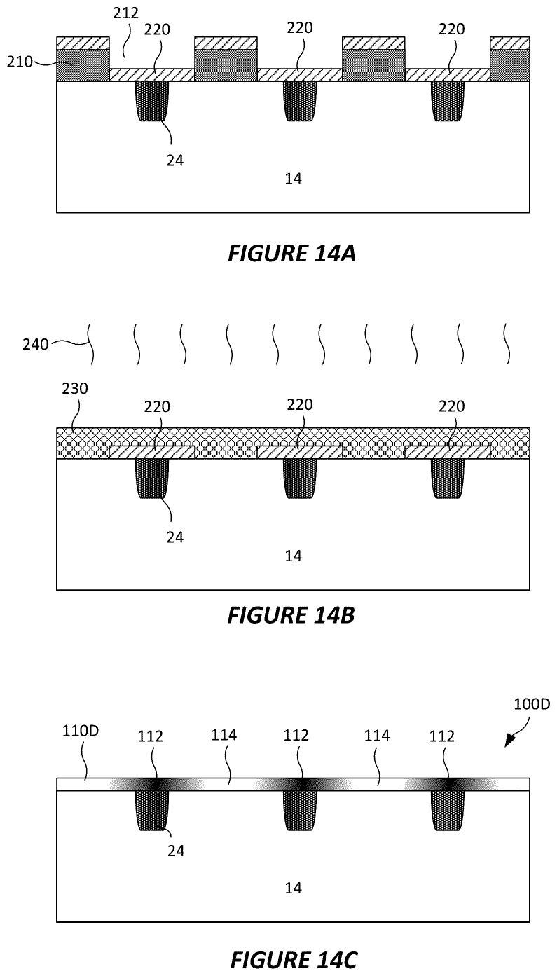

FIGS. 14A to 14C illustrate operations of forming a semiconductor device according to some embodiments. In particular, FIGS. 14A to 14C illustrate operations of forming a device structure 100D as shown in FIG. 9 in which the anode contact 110B is formed of a refractory metal nitride such as MoNₓ that has varying percentages of nitrogen across the active region. In particular, as shown in FIG. 9, the anode contact 110D includes first regions 112 of refractory metal nitride having a high percentage of nitrogen and second regions 114 of refractory metal nitride having a lower percentage of nitrogen.

Referring to FIG. 14A, a mask 210 is formed on the epitaxal layer 14. The mask 210 is patterned with openings 212 that expose portions of the epitaxial layer 14 in which the junction shielding regions 24 are formed. A blanket layer of a refractory metal nitride, such as MoNₓ, is deposited over the mask 210 and the exposed portions of the epitaxial layer 14. The mask 210 is the stripped, leaving the plurality of refractory metal nitride portions 220 on the epitaxial layer 14. A layer 230 of a non-nitride refractory metal, such as Mo, is then deposited over the structure. The layer 230 contacts the expitaxial layer 14 between the refractory metal nitride portions 220.

Referring to FIG. 14B, the structure is then subjected to heat 240 at a temperature sufficient to partially alloy the layer 230 and the refractory metal nitride portions 220. Referring to FIG. 14C, due to the heat treatment, some of the nitrogen in the refractory metal nitride portions 220 diffuses into the layer 230, resulting in the formation of first regions 112 of refractory metal nitride having a high percentage of nitrogen and second regions 114 of refractory metal nitride having a lower percentage of nitrogen. The first regions 112 are arranged above the junction shielding regions 24, while the second regions 114 are positioned above the epitaxial layer 14 in regions between the junction shielding regions 24. Because the first regions 112 have a higher nitrogen concentration, they may have a lower Schottky barrier height than the second regions 114, which have a lower nitrogen concentration. Due to diffusion, the nitrogen concentration of the layer may be smoothly graded between the first regions 112 and the second regions 114.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A Schottky diode, comprising:
a silicon carbide drift layer having a first conductivity type;
a junction shielding region in the drift layer, wherein the junction shielding region has a second conductivity type opposite the first conductivity type; and
an anode contact on the silicon carbide drift layer, wherein the anode contact comprises a refractory metal nitride, wherein the anode contact forms a Schottky junction with the drift layer, and wherein the anode contact forms an ohmic contact to the junction shielding region.

2. The Schottky diode of claim 1, wherein the anode contact has a Schottky barrier height relative to the drift layer of less than about 1.2 eV.

3. The Schottky diode of claim 1, wherein the anode contact has a Schottky barrier height relative to the drift layer of less than about 1 eV.

4. The Schottky diode of claim 1, wherein the anode contact comprises molybdenum (Mo) nitride.

5. The Schottky diode of claim 1, wherein the anode contact has a molecular ratio x of nitrogen of greater than about 0.5.

6. The Schottky diode of claim 1, wherein the anode contact has a molecular ratio x of nitrogen between about 1.0 and 1.6.

7. The Schottky diode of claim 1, wherein the anode contact has a thickness of at least about 50 nm.

8. The Schottky diode of claim 1, wherein the anode contact has a thickness of between about 80 nm and 300 nm.

9. The Schottky diode of claim 1, wherein the anode contact has a level of residual stress as deposited on the drift layer that has a magnitude of less than about 500 MPa.

10. The Schottky diode of claim 1, wherein the anode contact comprises a plurality of refractory metal nitride portions and a plurality of non-refractory metal nitride portions that are arranged in an alternating pattern along a surface of the drift layer, wherein the non-refractory metal nitride portions form a Schottky barrier junction with the drift layer that has a greater Schottky barrier height than the refractory metal nitride portions form with the drift layer.

11. The Schottky diode of claim 10, further comprising a plurality of junction shielding regions in the drift layer, wherein the refractory metal nitride portions are arranged above the junction shielding regions and form respective ohmic contacts with the junction shielding regions.

12. The Schottky diode of claim 11, wherein the non-refractory metal nitride portions contact the drift layer between adjacent junction shielding regions.

13. The Schottky diode of claim 12, wherein the non-refractory metal nitride portions comprise Ti and/or TiW.

14. The Schottky diode of claim 1, wherein the anode contact comprises alternating first and second regions along a surface of the drift layer, wherein the first regions have a first Schottky barrier height relative to the drift layer that is higher than a second Schottky barrier height of the second regions relative to the drift layer.

15. The Schottky diode of claim 14, wherein the first regions comprise MoNx and the second regions comprise MoNy, wherein x>y.

16. The Schottky diode of claim 15, wherein a nitrogen concentration in the anode contact is graded laterally between the first regions and the second regions.

17. The Schottky diode of claim 16, wherein a nitrogen concentration in the anode contact is smoothly graded between the first regions and the second regions.

18. The Schottky diode of claim 16, wherein a nitrogen concentration in the anode contact is stepwise graded between the first regions and the second regions.

19. The Schottky diode of claim 1, further comprising:
a plurality of trenches in an upper surface of the drift layer, wherein the anode contact comprises a plurality of refractory metal nitride portions in the trenches and a metal layer on the upper surface of the drift layer, wherein the metal layer contacts the refractory metal nitride portions.

20. The Schottky diode of claim 19, wherein the metal layer forms a first Schottky junction with the drift layer and the refractory metal nitride portions form second Schottky junctions with the drift layer, wherein the first Schottky junction has a higher Schottky barrier height than the second Schottky junctions.

21. The Schottky diode of claim 19, further comprising a plurality of junction shielding regions in the drift layer, wherein the junction shielding regions are arranged beneath respective ones of the trenches, and wherein the refractory metal nitride regions form ohmic contacts to respective ones of the junction shielding regions.

22. The Schottky diode of claim 19 wherein the refractory metal nitride regions comprise MoNx, and wherein the metal layer comprises molybdenum, titanium and/or tungsten.

23. The Schottky diode of claim 1, further comprising:
a plurality of silicide regions on the drift layer between the drift layer and the anode contact.

24. The Schottky diode of claim 23, wherein the silicide regions comprise MoSi.

25. The Schottky diode of claim 23, further comprising a plurality of junction shielding regions in the drift layer, wherein the plurality of silicide regions are arranged above respective ones of the plurality of junction shielding regions and form ohmic contacts to the junction shielding regions.

26. The Schottky diode of claim 25, wherein the silicide regions are provided within respective trenches in the drift layer, and wherein the junction shielding regions are beneath the trenches.

27. The Schottky diode of claim 26, wherein the anode contact extends into the trenches.

28. A method of forming a Schottky diode, comprising:
forming a drift layer on a substrate, wherein the drift layer and the substrate comprise silicon carbide and have a first conductivity type;
forming a junction shielding region at a surface of the drift layer, wherein the junction shielding region has a second conductivity type opposite the first conductivity type; and
forming an anode contact on the drift layer, wherein the anode contact comprises a refractory metal nitride, and wherein the anode contact forms a Schottky junction with the drift layer.

29. The method of claim 28, wherein the refractory metal nitride comprises MoNₓ.
